(19) United States
(12) Patent Application Publication
(10) Pub. No.: US 2018/0040566 A1
(43) Pub. Date: Feb. 8, 2018

(54) SYSTEM AND METHOD FOR FORMING AND AUTHENTICATING AN INTEGRATED CIRCUIT

(71) Applicant: HONEYWELL FEDERAL MANUFACTURING & TECHNOLOGIES, LLC, KANSAS CITY, MO (US)

(72) Inventors: DANIEL EWING, OVERLAND PARK, KS (US); WAYNE REED, LEES SUMMIT, MO (US); JAMES WILL, LEES SUMMIT, MO (US)

(73) Assignee: HONEYWELL FEDERAL MANUFACTURING & TECHNOLOGIES, LLC, KANSAS CITY, MO (US)

(21) Appl. No.: 15/229,501

(22) Filed: Aug. 5, 2016

(51) Int. Cl. H01L 23/544; H01L 21/02; H01L 21/265

(52) U.S. Cl. CPC H01L 23/544; H01L 21/26513; H01L 21/02667; H01L 2223/54413

(57) ABSTRACT

A system and method of forming an authenticatable integrated circuit comprising altering a material property of a semiconductor layer of the integrated circuit such that the semiconductor layer has physically unclonable functions (PUFs). The semiconductor layer may be subjected to ion implantation to form amorphous regions including the PUFs. The PUFs emit an electromagnetic signature having frequencies in the terahertz range when the PUFs are stimulated or interrogated by an authentication apparatus. The electromagnetic signature corresponds to identifying information of the integrated circuit. The integrated circuit can thus be authenticated without altering the electronic elements of the circuit and without the presence of discernable or discoverable identifying features.

### BACKGROUND

Integrated circuits often have identifying marks or unique features for authentication. For example, integrated circuits may have hidden serial numbers or specially-shaped electronic components identifying the integrated circuits as authentic. However, counterfeiters and other non-authorized entities often discover these identifying marks or unique features via reverse engineering, trial and error, or other techniques and incorporate them into counterfeit circuits, thus thwarting authentification efforts.

Adding authentication components also complicates circuit development. For example, some identifying marks or unique features are integrated into the circuits themselves, which adds more requirements to already complex designs. The very presence of unique features may also make an integrated circuit a target for being counterfeited, since more complicated circuits may be perceived as more profitable and/or important.

### SUMMARY

Embodiments of the invention solve the above-mentioned problems and provide a distinct advance in the art of authenticating integrated circuits. More particularly, the invention provides a system and method for forming an authenticatable integrated circuit in a way that is difficult to reverse engineer and that does not complicate the circuit design of the integrated circuit.

An embodiment of the invention is a method of forming an authenticatable integrated circuit comprising the steps of forming a semiconductor layer and altering a material property of the semiconductor layer such that the semiconductor layer has a physically unclonable function (PUF). The PUF emits an electromagnetic signature having frequencies in the terahertz range when the PUF is stimulated or interrogated by an authentication apparatus. The electromagnetic signature corresponds to identifying information of the integrated circuit. The integrated circuit can thus be authenticated without the inclusion of specially designed electronic elements and without adding discernable or discoverable identifying features to the integrated circuit.

Another embodiment of the invention is a method of authenticating an integrated circuit comprising stimulating a semiconductor layer of the integrated circuit such that a PUF of the semiconductor layer emits an electromagnetic signature having frequencies in the terahertz range and corresponding to identifying information of the integrated circuit. The electromagnetic signature is then sensed via a terahertz sensor. A value associated with a characteristic of the electromagnetic signature is then compared with a stored value in a circuit database. The stored value is associated with a previously-logged characteristic of electromagnetic signatures of known authenticated circuits.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the invention will be apparent from the following detailed description of the preferred embodiments and the accompanying drawing figures.

### BRIEF DESCRIPTION OF THE DRAWINGS

Embodiments of the invention are described in detail below with reference to the attached drawing figures, wherein:

FIG. 1 is a schematic cross-sectional view of an integrated circuit constructed according to embodiments of the invention, illustrating an electromagnetic signature being emitted from an amorphous region of the integrated circuit;

FIG. 2 is a top view of the integrated circuit of FIG. 1, illustrating ion implant regions of physically unclonable functions (PUFs) having varying material properties;

FIG. 3 is a block diagram of an authentication apparatus for analyzing an electromagnetic signature of the integrated circuit;

FIG. 4 is a flowchart illustrating a method of marking an integrated circuit with PUFs in accordance with embodiments of the invention; and

FIG. 5 is a flow chart illustrating a method of detecting and deciphering PUFs on the integrated circuit in accordance with an embodiment of the invention.

The drawing figures do not limit the invention to the specific embodiments disclosed and described herein. The drawings are not necessarily to scale, emphasis instead being placed upon clearly illustrating the principles of the invention.

### DETAILED DESCRIPTION

The following detailed description references the accompanying drawings that illustrate specific embodiments in which the invention may be practiced. The embodiments are intended to describe aspects of the invention in sufficient detail to enable those skilled in the art to practice the invention. Other embodiments can be utilized and changes can be made without departing from the scope of the invention. The following detailed description is, therefore, not to be taken in a limiting sense. The scope of the invention is defined only by the appended claims, along with the full scope of equivalents to which such claims are entitled.

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

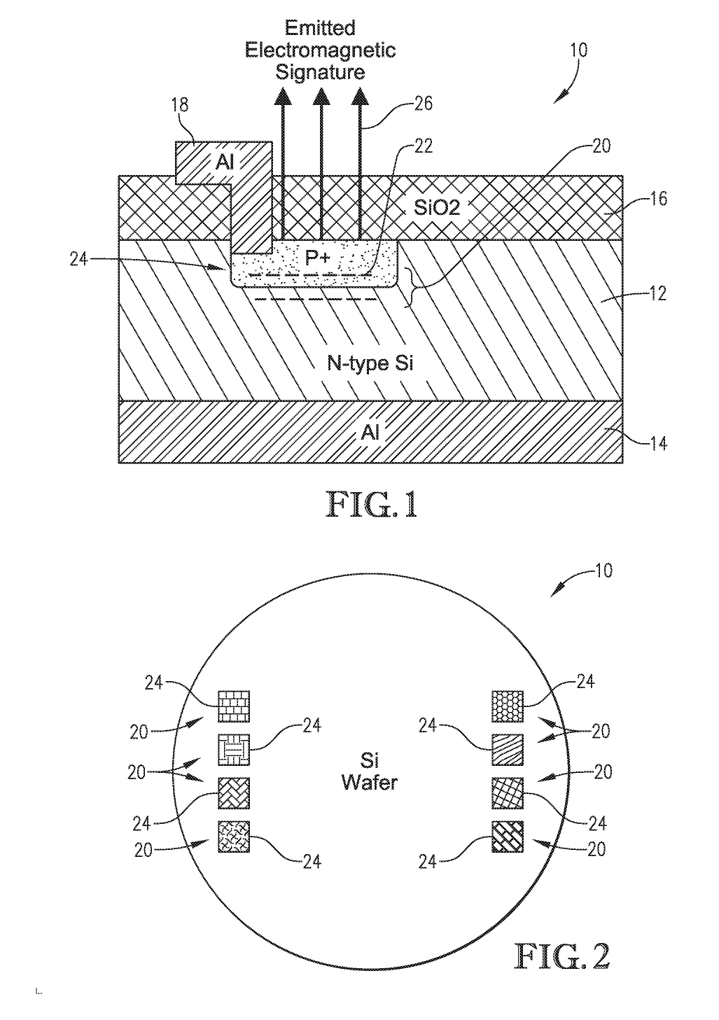

Turning to the drawing figures, an authenticatable integrated circuit 10 constructed in accordance with an embodiment of the invention is illustrated. The integrated circuit 10 broadly comprises a semiconductor layer 12, a conductive layer 14, a dielectric layer 16, and additional conductive layers 18, as shown in FIG. 1.

The semiconductor layer 12 forms a chip or wafer and acts as a base or substrate for the electronic elements 18. The semiconductor layer 12 may include crystal lattices and may be formed of any semiconductor material such as Si, SiGe, GaAs, GaN, or any combination thereof. The lattices may include amorphous regions 20 formed via ion implantation (described in more detail below). That is, the amorphous regions 20 may be altered as a result of interacting with high energy ions 22. The amorphous regions 20 may have predetermined locations, lengths, widths, depths, densities, degrees of recrystallization, material makeup, and other properties. The amorphous regions 20 form physically unclonable functions (PUFs) 24 that generate an electromagnetic signature 26 when stimulated, as described in more detail below. The amorphous regions 20 (and hence the PUFs 24) may be adjacent to each other or spaced apart from each other, as shown in FIG. 2.

The conductive layer 14 may be applied to a bottom side of the semiconductor layer 12 and may be formed of aluminum or any other suitable conductive material. It will be understood that the conductive layer 14 is optional and may take any form known in the art.

The dielectric layer 16 may be applied to a top side of the semiconductor layer 12 opposite the bottom side and may be formed of any dielectric material such as SiO₂. The dielectric layer 16 may be one of a number of dielectric layers for forming a multi-layered circuit.

The additional conductive layers 18 form portions of the circuit and may be conductive traces, buses, leads, vias, and/or other electronic components. The additional conductive layers 18 may be deposited or printed on the dielectric layer 16 and/or the semiconductor layer 12. The additional conductive layers 18 may extend at least partially through the dielectric layer 16 and the semiconductor layer 12 to form a multi-layered circuit.

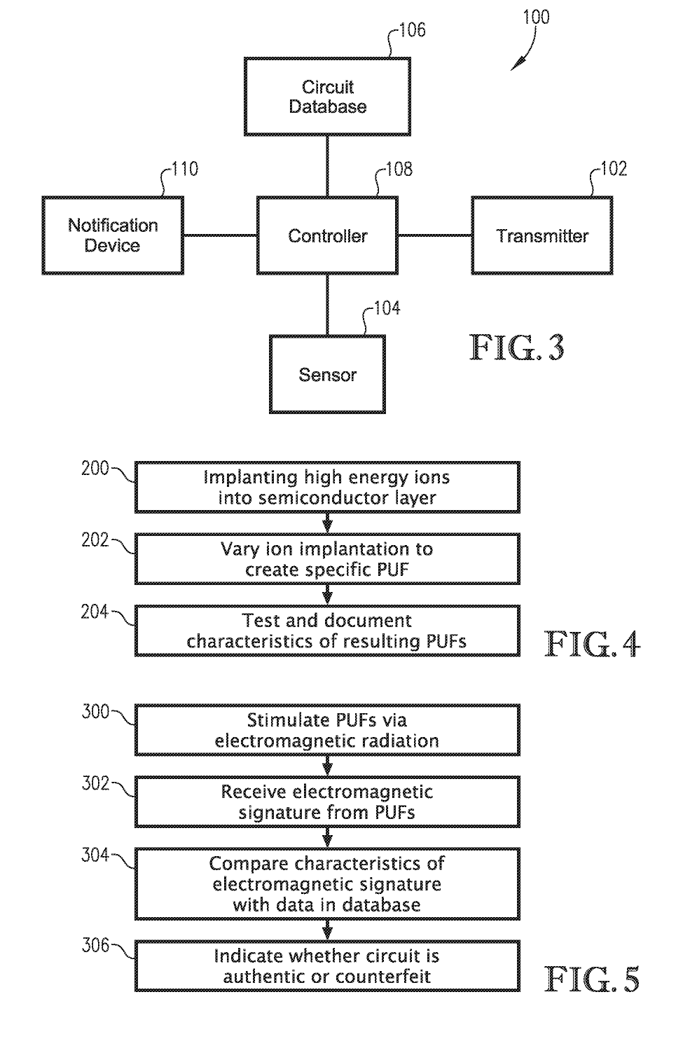

In accordance with an important aspect of the invention, the integrated circuit may be documented and/or authenticated via an authentication apparatus 100. The authentication apparatus 100 broadly includes an electromagnetic transmitter 102, sensor 104, a circuit database 106, a controller 108, and/or a notification device 110, as shown in FIG. 3. The authentication apparatus 100 may be or may incorporate or communicate with a desktop computer, laptop, tablet, smart phone, PDA, or any other computing device.

The transmitter 102 emits optical or electromagnetic radiation for interrogating the integrated circuit 10 and may be positioned near the sensor 104 and/or the controller 108 and may be configured to be aimed at the integrated circuit 10. The transmitter 102 may be a standalone component or may be integrated into the authentication apparatus. In one embodiment, the transmitter 102 is a laser source.

The sensor 104 detects electromagnetic radiation in the terahertz range being emitted from or reflected by the integrated circuit 10. The sensor 104 may be configured to be positioned close to and/or aimed at the integrated circuit 10 for receiving and/or quantifying the electromagnetic radiation when the integrated circuit 10 is stimulated by the transmitter 102 or otherwise activated.

The circuit database 106 stores electromagnetic signatures or other identifiable data of the PUFs 24 and may comprise residential or external memory that may be integral with the authentication apparatus 100 or stand-alone. The memory may include, for example, removable and non-removable memory elements such as RAM, ROM, flash, magnetic, optical, USB memory devices, MMC cards, RS MMC cards, SD cards such as microSD or miniSD, SIM cards, and/or other memory elements. The circuit database 106 may store, for example, keys, codes, variables, or other values corresponding to the PUFs 24.

The controller 108 controls operation of the transmitter 102, sensor 104, and circuit database 106 and may comprise any combination of processors, circuits, programmable logic devices such as programmable logic controllers (PLC), computers, microcontrollers, transmitters, receivers, residential or external memory devices, and other electrical or computing devices. The controller 108 may be configured to analyze signals received by the sensor 104 and compare characteristics of the signals or data embedded in the signals against values or data stored on the circuit database 106.

The controller 108 may be configured to implement any combination of algorithms, subroutines, computer programs, or code corresponding to method steps and functions described herein. The controller 108 and computer programs described herein are merely examples of computer equipment and programs that may be used to implement the invention and may be replaced with or supplemented with other controllers and computer programs without departing from the scope of the invention. While certain features are described as residing in the controller 108, it will be understood that those features may be implemented elsewhere. For example, the circuit database 106 may be remotely accessed by the controller 108 over a wireless communication network such as the internet or a telecommunications network.

As mentioned above, the controller 108 may implement the computer programs and/or code segments to perform various method steps described herein. The computer programs may comprise an ordered listing of executable instructions for implementing logical functions in the controller. The computer programs can be embodied in any computer-readable medium for use by or in connection with an instruction execution system, apparatus, or device, and execute the instructions. In the context of this application, a “computer-readable medium” can be any physical medium that can contain, store, communicate, propagate, or transport the program for use by or in connection with the instruction execution system, apparatus, or device. The computer-readable medium can be, for example, but not limited to, an electronic, magnetic, optical, electro-magnetic, infrared, or semi-conductor system, apparatus, or device. More specific, although not inclusive, examples of the computer-readable medium would include the following: an electrical connection having one or more wires, a portable computer diskette, RAM, ROM, an erasable, programmable, read-only memory (EPROM or Flash memory), a portable compact disk read-only memory (CDROM), an optical fiber, MMC, SD cards such as microSD or miniSD, and a SIM card.

The notification device 110 indicates whether an integrated circuit being interrogated is authentic or not and may be a user interface, visual display device, and/or speaker, any of which may communicate visually or audibly. For example, the visual display device may be a computer screen or may simply be one or more LEDs configured to visually indicate if an integrated circuit is determined by the controller 108 to be authentic or counterfeit. Additionally or alternatively, the speaker may be configured to output an audible indication to the user regarding the authenticity of the integrated circuit 10. In some embodiments of the invention, the notification device 110 may further include a wireless transmitter configured to transmit information from the controller 108 to a remote notification device, such as another computer, tablet, smart phone, or the like.

Forming the amorphous regions 20 of the authenticatable integrated circuit 10 will now be described in more detail. First, the crystal lattices of the semiconductor layer 12 may be altered when interacting with high energy ions 22 transmitted towards the semiconductor layer 12 via ion implanters and/or focused ion beam tools, as shown in block 200 of FIG. 4. The ions 22 may be implanted at a number of adjacent or spaced locations corresponding to the predetermined PUF locations at a number of locations. The ions 22 will no longer have high energy after implantation.

The ion implantation may be varied to create the specific PUFs 24, as shown in block 202. For example, accelerating energy or accelerating voltage may be varied (purposefully or via small uncontrolled variations) to modify the depth of the amorphous regions 20. An ion implantation species may be varied or selected to change the polarity of the PUFs 24 and hence the electromagnetic signature 26. An ion implantation dose may be selected or varied to modify an amplitude of the electromagnetic signature 26. The amorphous regions 20 may also be heated to a predetermined temperature and/or for a predetermined time to vary the degree of recrystallization of the amorphous regions 20. The amorphous regions 20 may be altered according to a two-dimensional plan such that the electromagnetic signature 26 is at least partially defined by the two-dimensional plan. The ion implantation may be performed such that the PUFs 24 and hence the electromagnetic signature 26 are at least partially corresponds to a model of the integrated circuit 10, while the PUFs 24 and hence the electronic signature 26 are at least partially unique to the specific integrated circuit 10 being formed.

The PUFs 24 of the integrated circuit 10 may then be tested and documented, as shown in block 204. That is, for each known authentic integrated circuit, a group of values associated with characteristics of the PUFs 24 for that authentic integrated circuit may be stored in the circuit database 106. For example, the positions or relative positions of the PUFs 24, the lengths, widths, and/or depths of the PUFs 24, and/or the amplitude, polarity, and/or frequencies of the electromagnetic signature 26 may be determined and stored in the circuit database 106 for later authentication. Alternatively, values or ranges of values may be used to identify a make, model, or part number of the integrated circuits.

Authenticating an integrated circuit will now be described in more detail. First, the controller 108 may instruct the transmitter 102 to emit optical or electromagnetic radiation, as shown in block 300 of FIG. 5. To that end, the transmitter 102 may be positioned near or aimed at the integrated circuit being tested. The integrated circuit may be a bare die or enclosed in standard packaging. However, the integrated circuit does not need be made accessible or removed from the packaging for the electromagnetic radiation to reach and excite the PUFs 24 of the integrated circuit 10. Nevertheless, the transmitter 102 may need to be aimed towards a specific portion of the integrated circuit to interrogate the PUFs 24.

The electromagnetic signature 26 generated by the PUFs 24 in response to the interrogation may then be received via the sensor 104, as shown in block 302. The sensor 104 may convert the electromagnetic signature 26 into an electronic signal for the controller 108 to interpret.

The controller 108 may then analyze the electromagnetic signature 26 by comparing characteristics or values of the electromagnetic signature 26 with data stored in the circuit database 106, as shown in block 304. For example, the positions or relative positions of the PUFs 24, the lengths, widths, and/or depths of the PUFs 24, and/or the amplitude, polarity, and/or frequencies of the electromagnetic signature 26 may be compared with similar characteristics stored in the circuit database 106. The controller 108 may determine whether the integrated circuit being tested is authentic or counterfeit based on whether predetermined characteristics of the electromagnetic signature 26 match or are within a predetermined range of corresponding data in the circuit database 106.

The controller 108 may then instruct the notification device 110 to indicate whether the integrated circuit is authentic or counterfeit, as shown in block 306. For example, the notification device 110 may emit a green light if the integrated circuit is authentic and a red light if the integrated circuit is counterfeit. Alternatively, the notification device 110 may only provide an indication if the integrated circuit is determined to be authentic or conversely if the integrated circuit is determined to be counterfeit. The notification device 110 may also display a make, model, or unit number of the integrated circuit if the integrated circuit is authentic.

The above-describe authenticatable integrated circuit 10 and authentication apparatus 100 provide several advantages over conventional integrated circuits and authentication apparatuses. For example, the PUFs 24 of the integrated circuit 10 do not require on-chip power to generate the electromagnetic signature 26. That is, the electromagnetic signature 26 can be passively generated when the integrated circuit 10 is interrogated. The PUFs 24 also do not require complex circuitry and do not require the additional conductive layers 18 of the integrated circuit 10 to be modified or adapted to be accommodated into the integrated circuit 10. The PUFs 24 are not visible and are not otherwise easily identifiable, which makes it nearly impossible for competitors or counterfeiters to reverse engineer, or even be aware of, the existence of the PUFs 24. Even if the existence of the PUFs 24 are known, the exact specifications of the PUFs 24 are nearly impossible to detect and/or replicate. The integrated circuit 10 can be authenticated without dismantling the electronic device in which it is incorporated because the electromagnetic signature 26 has frequencies in the terahertz range, which readily travel through electronic device housings. The integrated circuit 10 and the authentication apparatus 100 can be used in commercial applications to prevent loss of marketshare and in defense applications to provide a simple test-and-detect method to ensure a trusted supply chain for critical microelectronic devices.

Having thus described various embodiments of the invention, what is claimed as new and desired to be protected by Letters Patent includes the following:

1. A method of forming an authenticatable integrated circuit, the method comprising the steps of:
forming a semiconductor layer having a plurality of crystal lattices;
subjecting the crystal lattices at a plurality of predetermined spaced locations to a predetermined ion implantation dose so as to form amorphous regions having predetermined lengths, widths, depths, and densities, the step of subjecting the crystal lattices to a predetermined ion implantation dose including the sub-steps of:
selecting an accelerating energy or accelerating voltage for modifying the depths of the amorphous regions, and
selecting an ion implantation species; and
heating the amorphous regions to a predetermined temperature for a predetermined time so as to vary a degree of recrystallization of the amorphous regions
such that the semiconductor layer has a physically unclonable function (PUF) configured to emit an electromagnetic signature having frequencies in the terahertz range when the PUF is interrogated via a single laser source, the electromagnetic signature corresponding to identifying information of the integrated circuit, a polarity of the PUF and hence the electromagnetic signature being determined by the selected ion implantation species, an amplitude of the electromagnetic signature being determined according to the ion implantation dose, the PUF and hence the electromagnetic signature at least partially corresponding to a model of the integrated circuit.

2-12. (canceled)

13. The method of claim 1, wherein the semiconductor layer is altered according to a two-dimensional plan, the electromagnetic signature being at least partially defined by the two-dimensional plan.

14. (canceled)

15. A method of authenticating an integrated circuit, the method comprising the steps of:
interrogating a physically unclonable function of a semiconductor layer of the integrated circuit such that the physically unclonable function emits an electromagnetic signature having frequencies in the terahertz range, the electromagnetic signature corresponding to identifying information of the integrated circuit;
sensing via a terahertz sensor the electromagnetic signature; and
comparing a value associated with a characteristic of the electromagnetic signature with a stored value in a circuit database, the stored value being associated with a previously-logged characteristic of electromagnetic signatures of known authenticated circuits.

16. The method of claim 15, wherein the characteristic of the electromagnetic signature is amplitude.

17. The method of claim 15, wherein the characteristic of the electromagnetic signature is polarity.

18. The method of claim 15, wherein the characteristic of the electromagnetic signature corresponds to a geometric mapping of an alteration of the semiconductor layer.

19. The method of claim 15, wherein the electromagnetic signature is at least partially unique to the integrated circuit.

20. An authenticatable integrated circuit comprising:
a semiconductor layer having a plurality of amorphous regions forming physically unclonable functions (PUFs) configured to emit an electromagnetic signature having frequencies in the terahertz range, the amorphous regions having predetermined lengths, widths, and depths, the electromagnetic signal having a pre-determined polarity and amplitude and corresponding to a model of the integrated circuit;
a conductive layer positioned on a first side of the semiconductor layer;
a dielectric layer positioned on a second side of the semiconductor layer opposite the first side; and
a plurality of electronic elements positioned on the dielectric layer, the electronic elements being independent from the amorphous regions of the semiconductor layer.

21. The method of claim 1, further comprising the steps of:
determining a group of values associated with characteristics of the PUF, the group of values including a length, width, and depth of the PUF and an amplitude, polarity, and frequency of the electromagnetic signature; and
storing the group of values in a circuit database.
